(19) United States
(12) Patent Application Publication
(10) Pub. No.: US 2015/0062828 A1
(43) Pub. Date: Mar. 5, 2015

(54) Connector, connector Assembly, and Wireless Communication Module

(71) Applicant: Tyco Electronics Japan G.K., Kawasaki-shi (JP)

(72) Inventor: Hiroshi Shirai, Saitama (JP)

(73) Assignee: Tyco Electronics Japan G.K., Kawasaki-shi (JP)

(21) Appl. No.: 14/087,708

(22) Filed: Nov. 22, 2013

(30) Foreign Application Priority Data
Sep. 2, 2013 (JP) 2013-18170

(51) Int. Cl. H01R 13/62; H05K 1/18

(52) U.S. Cl. CPC H01R 13/6205; H05K 1/181
USPC 361/728; 439/39

(57) ABSTRACT

A connector is provided that is capable of high-speed transmission over a carrier wave of, for example, 30 GHz or higher. The connector includes a housing, a wireless communication module and a first magnet. The housing includes a planar face, and the wireless communication module is disposed in the housing and includes a wireless signal transmission IC and a wireless signal reception IC. The first magnet is disposed along the planar face.

### CROSS-REFERENCE TO RELATED APPLICATIONS

This application claims the benefit of the filing date under 35 U.S.C. §119(a)-(d) of Japanese Patent Application No. 2013-181170 of Sep. 2, 2013.

### FIELD OF INVENTION

The present invention relates to a connector and, in particular, to a connector assembly having a magnet.

### BACKGROUND

There are known connectors that use magnets for connection to one another.

For instance, FIG. 13 shows an example of the above-mentioned known connector (see U.S. Pat. No. 7,311,526 B). The connector 101 shown in FIG. 13 includes a first connector 110 connected to a first device A such as a transformer; and a second connector 120 connected to a second device B such as a laptop computer.

The first connector 110 includes a housing 111, and the housing 111 includes a pair of first contacts 112 made of metal. Each of the first contacts 112 is received in a contact receiving space 114 formed in a mating face 117 of the housing 111. Each of the first contacts 112 is connected to the first device A through a cable 116. Then, a spring 113 is arranged in each contact receiving space 114, and each of the first contacts 112 is biased by the spring 113 to protrude from the mating face 117 of the first connector 110. In addition, an magnet 115 is arranged in the mating face 117 between the pair of the first contacts 112 in the first connector 110.

On the other hand, the second connector 120 includes a housing 121, and the housing 121 includes a pair of second contacts 122 made of metal. Each of the second contacts 122 is embedded in the housing 121 and exposed to a mating face 124 of the housing 121. Each of the second contacts 122 is connected to an internal device 126 through an electrical wire 125. In addition, an magnet 123 is arranged in the mating face 124 between the pair of the second contacts 122 in the housing 121.

When the first connector 110 is connected to the second connector 120, the first contacts 112 make contact with the second contacts 122 and both of the connectors 110 and 120 are electrically connected. In this situation, the magnet 115 of the first connector 110 and the magnet 123 of the second connector 120 are attracted to each other, so that the connection state of both connectors 110 and 120 can be maintained.

In this manner, the magnets 115 and 123 to be attracted to each other are used to maintain the connection between the first and second connectors 110, 220 using a simple structure.

Now with respect to FIG. 14, a known signal connection apparatus is shown (see Japanese Patent Application No. JP 2005-6022 A).

FIG. 14 shows two sets of signal connection apparatuses 201a and 201b. Electrical current generated at microprocessors 202a and 202b are supplied to drive circuits 203a and 203b, respectively. Then, direct currents obtainable on the output sides of the drive circuits 203a and 203b are supplied to attraction coils 205a and 205b wound around magnetic substances 204a and 204b.

Further, transmission signals obtained at the microprocessors 202a and 202b are supplied to power amplifier circuits 206a and 206b for transmission. The transmission signals obtained by the power amplifier circuits 206a and 206b are supplied to signaling coils 207a and 207b wound around the magnetic substances 204a and 204b. In this case, the signaling coils 207a and 207b are capable of transmitting the transmission signals by electromagnetic coupling, when closer to each other to a predefined distance.

Additionally, reception signals obtainable at the signaling coils 207a and 207b are supplied through capacitors 208a and 209b to reception signal detecting amplifier circuits 209a and 209b, respectively. Then, the reception signals amplified by the amplifier circuits 209a and 209b are supplied through comparators 210a and 210b to the microprocessors 202a and 202b.

The microprocessors 202a and 202b are respectively connected to personal computers 211a and 211b for various types of control.

In the two sets of signal connection apparatuses 201a and 201b, when the signaling coils 207a and 207b wound around the magnetic substances 204a and 204b are made closer to each other by a predefined distance, the transmission signals are transmitted to each other by the electromagnetic coupling. Further, the attraction currents are supplied to the attraction coils 205a and 205b, thereby mechanically coupling the magnetic substances 204a and 204b, as electromagnets.

It is to be noted that, however, in the connector 101 shown in FIG. 13 and the signal connection apparatus shown in FIG. 14, according to the known examples, there are following problems.

In the case of the connector 101 shown in FIG. 13, in order to be able to make contact with the second contacts 122, the first contacts 112 are provided extend from the mating face 117 of the housing 111. For this reason, the appearance is impaired in view of its design and is not desirable.

On the other hand, in the case of the signal connection apparatus shown in FIG. 14, when the signaling coils 207a and 207b wound around the magnetic substances 204a and 204b are made closer to each other by a predefined distance, the transmission signals are transmitted to each other by the electromagnetic coupling. This eliminates the necessity of electrical contact between the contacts. Hence, it is not necessary that the contacts protrude from the housing, thereby posing no problem in its design (appearance).

It is to be noted that, however, since the signal connection apparatus shown in FIG. 14 has a purpose of achieving the mechanical coupling and the bidirectional signal connection by use of the magnetic substances 204a and 204b and the coils 205a, 205b, 207a, and 207b, it cannot achieve the high-speed transmission over a carrier wave of 30 GHz or higher necessary for transmission and reception of signals at 3 Gbps or more, for example. In fact, paragraph 0049 of JP 2005-6022 A discloses that “the transmission at 10 MHz or 100 MHz is not available”.

### SUMMARY

Therefore, the invention has been made to solve these problems, among others, and has provides a connector suitable for high-speed transmission over a carrier wave of, for example, 30 GHz or higher, and being superior in design, a connector assembly, and a wireless communication module.

A connector is provided that is capable of high-speed transmission over a carrier wave of, for example, 30 GHz or higher. The connector includes a housing, a wireless communication module and a first magnet. The housing includes a planar face, and the wireless communication module is disposed in the housing and includes a wireless signal transmission IC and a wireless signal reception IC. The first magnet is disposed along the planar face.

### BRIEF DESCRIPTION OF THE DRAWINGS

FIG. 1 is a perspective view of a connector assembly according to the invention, and a first connector connectable a mobile device having a second connector;

FIG. 2 is a perspective view of the connector assembly of FIG. 1, and the first connector connected a mobile device having a second connector;

FIG. 3 is a perspective view of the first connector according to the invention;

FIG. 4A is a plan view of the first connector of FIG. 3;

FIG. 4B is a front view of the first connector of FIG. 3;

FIG. 5 is a right side view of the first connector of FIG. 3, showing a wireless communication module and an magnet of the first connector with hidden lines;

FIG. 6 is a perspective view of the wireless communication module of the first connector according to the invention;

FIG. 7A is a top view of the wireless communication module of FIG. 6;

FIG. 7B is a bottom view of the wireless communication module of FIG. 6;

FIG. 8 is perspective view of a wireless communication module for the second connector according to the invention;

FIG. 9 is a circuit block diagram of the wireless communication modules of the first and second connectors according to the invention;

FIG. 10 is a perspective view of another second connector of the connector assembly according to the invention;

FIG. 11A is a plan view of the second connector of FIG. 10;

FIG. 11B is a front view of the second connector of FIG. 10;

FIG. 12A is a bottom view of the second connector of FIG. 10;

FIG. 12B is a back view of the second connector of FIG. 10;

FIG. 13 is a cross-sectional view of a known connector; and

FIG. 14 is an electrical schematic of a known signal connection apparatus.

### DETAILED DESCRIPTION OF THE EMBODIMENT(S)

Hereinafter, embodiments of the invention will be described with reference to the drawings.

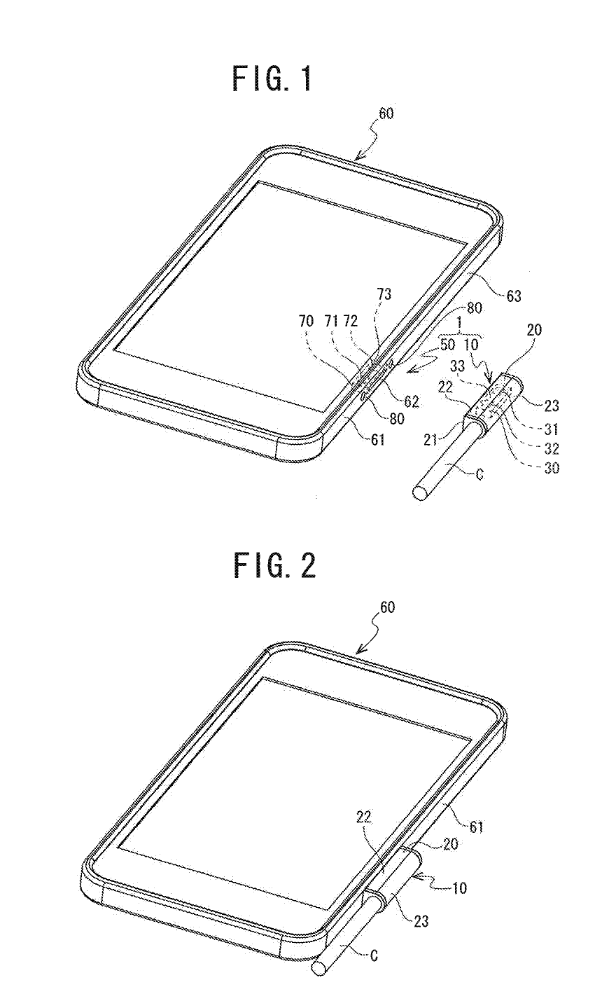

With reference to FIGS. 1 and 2, a connector assembly 1 according to the invention includes a first connector 10 and a second connector 50 to be connected each other. The first connector 10 is connected to a cable C, whereas the second connector 50 is disposed in device, such as a mobile device 60 (i.e. a smart phone). When the first connector 10 is connected to the second connector 50, a wireless communication module 30 of the first connector 10 and a wireless communication module 70 of the second connector 50 perform high-speed data transmission over the carrier wave of, for example, 30 GHz or more. This data communication will be described later.

In this situation, as shown in FIG. 1 and FIGS. 3-5, the first connector 10 includes a housing 20; a wireless communication module 30 mounted in the housing 20; and a pair of magnets 40 disposed in the housing 20.

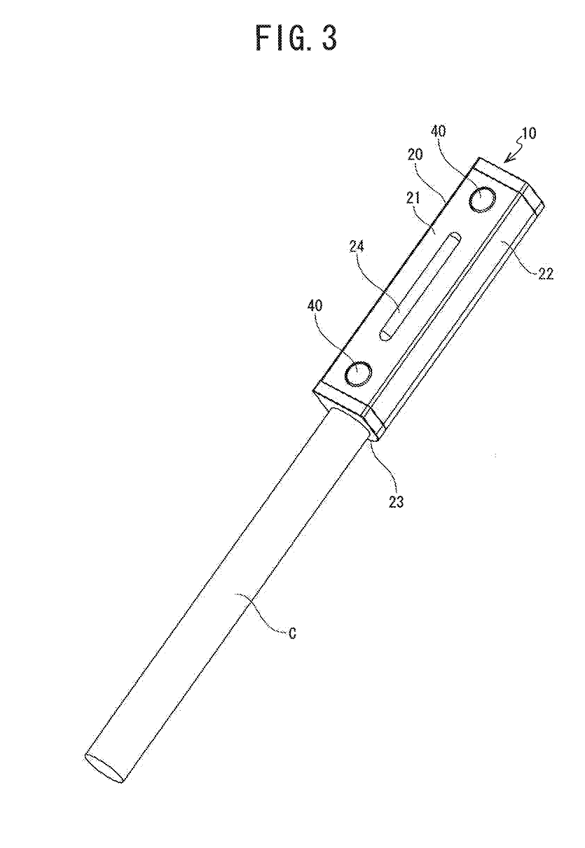

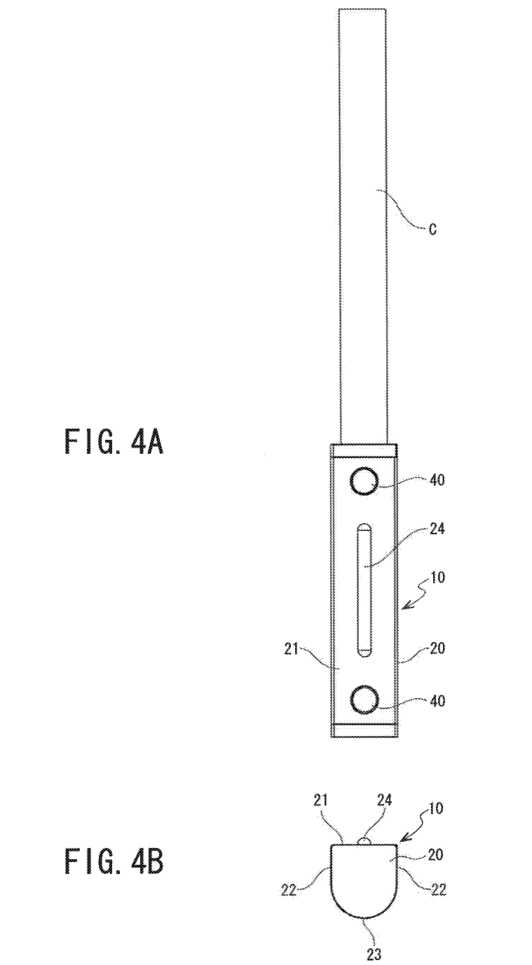

The housing 20 is elongated along a direction that the cable C extends, as shown in FIG. 3 to FIG. 5. The housing 20 includes a rectangular planar face 21 that extends along a length direction common to that which the cable C extends, a pair of sides 22 that extend downward perpendicularly from both sides of the planar face 21; and a curved portion 23 that couples both of the sides 22 and protrudes from the bottom side. The housing 20 is made by molding an insulating synthetic resin. In addition, as shown in FIG. 4A and FIG. 4B, the planar face 21 of the housing 20 has a first positioning portion 24 to be positioned to the second connector 50 which extends in an elongated shape in a length direction of the housing 20.

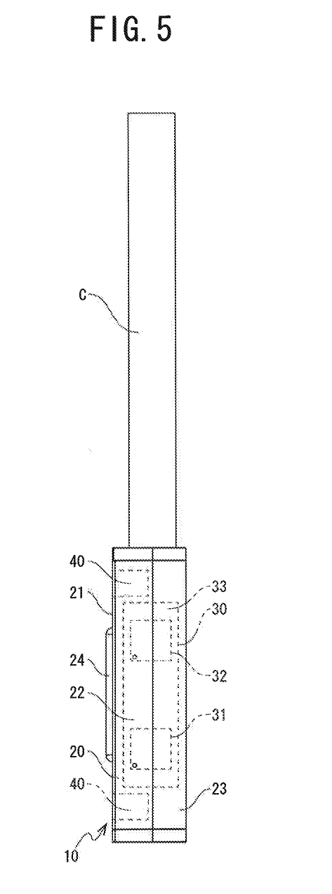

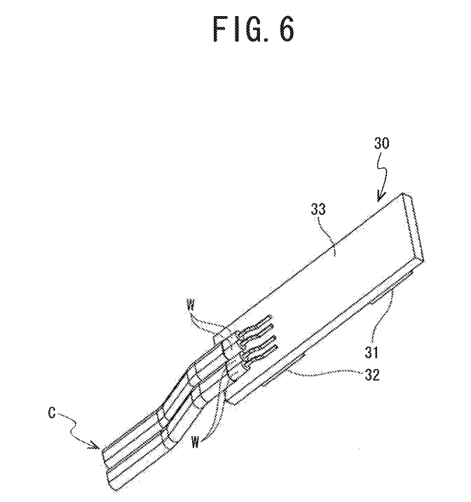

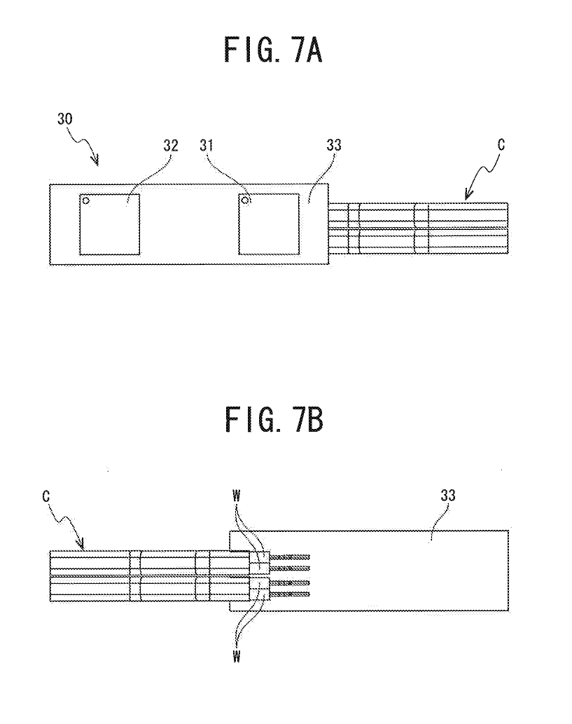

Further, as shown in FIG. 6, FIG. 7A and FIG. 7B, the wireless communication module 30 includes a circuit board 33; a wireless signal transmission IC 31; and a wireless signal reception IC 32. The wireless signal transmission IC 31 and the wireless signal reception IC 32 are mounted on the rectangular circuit board 33 with a length direction extending in the direction that the cable C extends, as shown in FIG. 7A. The wireless signal transmission IC 31 and the wireless signal reception IC 32 are mounted on the circuit board 33 spaced apart from each other by a predefined interval in the length direction of the circuit board 33. The circuit board 33 is disposed in the housing 20 such that the shorter side thereof is orthogonal to the planar face 21, as shown in FIG. 5.

In this situation, as shown in FIG. 9, the wireless signal transmission IC 31 transmits signals to a wireless signal reception IC 72 of the wireless communication module 70 in the second connector 50, and includes a buffer 31a, a modulation circuit 31b, an amplifier circuit 31c, and an antenna 31d. The buffer 31a receives the high-speed digital signals, and the modulation circuit 31b modulates the high-speed digital signals into high-frequency signals including carrier waves. Then, the amplifier circuit 31c amplifies the high-frequency signals so as to be emitted as electrical waves from the antenna 31d.

On the other hand, as shown in FIG. 9, the wireless signal reception IC 32 receives the electrical waves from a wireless signal transmission IC 71 of the wireless communication module 70 in the second connector 50, and includes an antenna 32a, a low-noise amplifier 32b, and a demodulation circuit 32c.

As shown in FIG. 6, FIG. 7A, and FIG. 7B, multiple (four) electrical wires W of the cable C are connected to the circuit board 33.

Additionally, as shown in FIG. 5, the pair of magnets 40 are arranged on both sides in the length direction to interpose the wireless communication module 30 (the circuit board 33) there between. Then, each magnet 40 is cylindrical shaped, and is exposed with one end face thereof being almost flush with the planar face 21 of the housing 20. When the first connector 10 and the second connector 50 are connected, each magnet 40 attracts each magnet 80, as will be described later, provided on the second connector 50 side with each other to achieve the mechanical coupling of both of the connectors 10 and 50. Further, the power transmission is made possible by the magnet 40 of the first connector 10 and the magnet 80 of the second connector 50.

Next, the second connector 50 is disposed in the mobile device 60, as shown in FIG. 1. The second connector 50 includes a housing 61 having a chassis for the mobile device 60, the wireless communication module 70 mounted in the housing 61, and a pair of magnets 80 disposed in the housing 61.

The housing 61 is has a substantially rectangular shape to surround the outer circumference of the mobile device 60, when viewed from the planar face. A positioning portion 62 to position the first connector 10 extends in an elongated shape in a length direction of the housing 61, on a side face 63 extending in the length direction of the housing 61. The first positioning portion 24 of the first connector 10 enters the second positioning portion 62 of the second connector 50 to position both of the connectors 10 and 50.

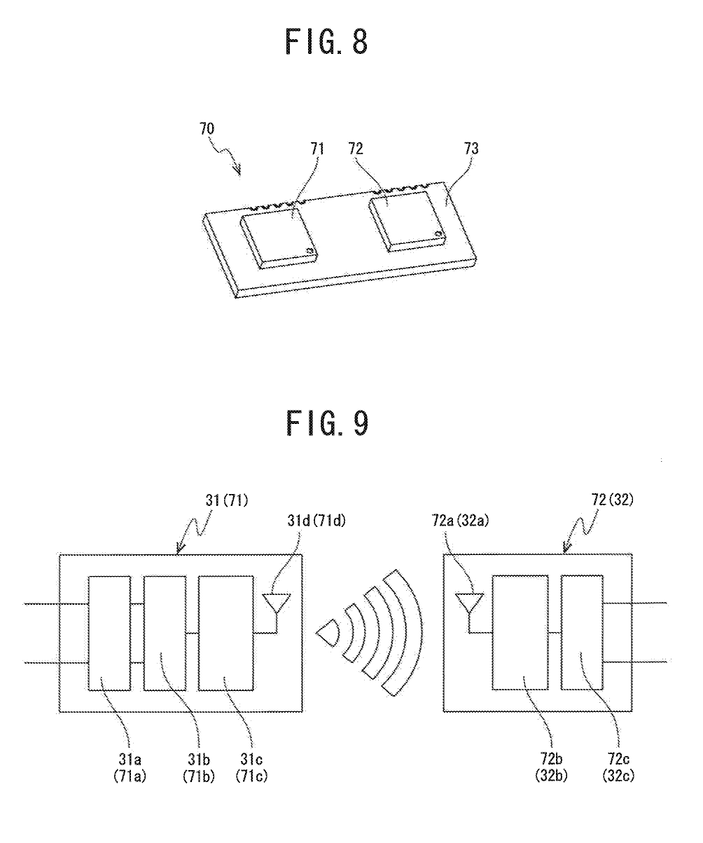

Moreover, as shown in FIG. 1 and FIG. 8, the wireless communication module 70 includes a circuit board 73, the wireless signal transmission IC 71, and the wireless signal reception IC 72. The wireless signal transmission IC 71 and the wireless signal reception IC 72 are mounted on the circuit board 73. The wireless signal transmission IC 71 and the wireless signal reception IC 72 are mounted on the circuit board 73 to be spaced apart from each other by a predefined interval along a length of the circuit board 73. The circuit board 73 is disposed in the housing 61 such that the shorter side thereof is orthogonal to the side face 63, as shown in FIG. 1.

In this situation, the wireless signal transmission IC 71 transmits signals to the wireless signal reception IC 32 of the wireless communication module 30 in the first connector 10, as shown in FIG. 9, and includes a buffer 71a, a modulation circuit 71b, an amplifier circuit 71c, and an antenna 71d. The buffer 71a receives the high-speed digital signals, and the modulation circuit 71b modulates the high-speed digital signals into high-frequency signals including carrier waves. Then, the amplifier circuit 71c amplifies the high-frequency signals so as to be emitted as electrical waves from the antenna 71d.

On the other hand, the wireless signal reception IC 72 receives the electrical waves from the wireless signal transmission IC 31 of the wireless communication module 30 in the first connector 10, as shown in FIG. 9, and includes an antenna 72a a low-noise amplifier 72b, and a demodulation circuit 72c.

The circuit board 73 is connected to a circuit board, not shown, in the mobile device 60.

Additionally, as shown in FIG. 1, the pair of magnets 80 are arranged on both sides to interpose the wireless communication module 70 (the circuit board 73) there between. Then, each magnet 80 has a cylindrical shape, and is exposed with one end face thereof being almost flush with the side face 63 of the housing 61.

Now, a connection between the first connector 10 and the second connector 50 will now be described.

Firstly, as shown in FIG. 1, the planar face 21 of the first connector 10 and the side face 63 of the second connector 50 face each other to make each magnet 40 on the planar face 21 of the first connector 10 closer to each magnet 80 on the side face 63 of the second connector 50.

This causes each magnet 40 of the first connector 10 and each magnet 80 of the second connector 50 to attract each other, so that the first connector 10 and the second connector 50 are mechanically connected.

In this situation, the first positioning portion 24 of the first connector 10 enters the second positioning portion 62 of the second connector 50, and the first connector 10 is positioned with respect to the second connector 50.

It is thus made possible for the wireless communication module 30 of the first connector 10 and the wireless communication module 70 of the second connector 50 to perform data communication at high-speed transmission over the carrier wave of, for example, 30 GHz or higher. Specifically, the wireless signal transmission IC 31 of the wireless communication module 30 in the first connector 10 and the wireless signal reception IC 72 of the wireless communication module 70 in the second connector 50 are capable of performing the data communication with each other. Additionally, the wireless signal reception IC 32 of the wireless communication module 30 in the first connector 10 and the wireless signal transmission IC 71 of the wireless communication module 70 in the second connector 50 are capable of performing the data communication with each other. Furthermore, the magnet 40 of the first connector 10 and the magnet 80 of the second connector 50 are capable of performing the power transmission with each other.

In this manner, since the wireless communication module 30 of the first connector 10 and the wireless communication module 70 of the second connector 50 are capable of performing the data communication, it is possible to provide the connector assembly 1 suited for the high-speed transmission over the carrier wave of, for example, 30 GHz or higher. Moreover, the wireless communication module 30 is mounted in the housing 20 and the wireless communication module 70 is mounted in the housing 61. This eliminates a need for providing a contact to protrude from the planar face 21 of the housing 20 or from the side face 63 of the housing 61, thereby resulting in the connector assembly 1 superior in design.

As described above, when the first connector 10 and the second connector 50 are connected to each other, the first positioning portion 24 of the first connector 10 enters the second positioning portion 62 of the second connector 50, and the first connector 10 is positioned with respect to the second connector 50. Accordingly, no misalignment occurs at either of the first connector 10 or the second connector 50, and the data communication can be performed smoothly.

In addition, in the first connector 10, the pair of the magnets 40 are arranged to interpose the wireless communication module 30 there between. Further, in the second connector 50, the pair of the magnet 80 are arranged to interpose the wireless communication module 70 there between. Therefore, when each magnet 40 of the first connector 10 and each magnet 80 of the second connector 50 are attracted to each other, each magnet 40 and 80 are attracted to each other on both sides interposing the wireless communication module 30 and the wireless communication module 70 in a stable manner, respectively. If a single magnet of the first connector 10 and a single magnet of the second connector 50 are provided and attracted to each other, the magnets may turn at the time of attraction. For this reason, in a case where only one magnet is arranged for each of the first connector 10 and the second connector 50, it is necessary to provide a means for mechanically suppress any turning.

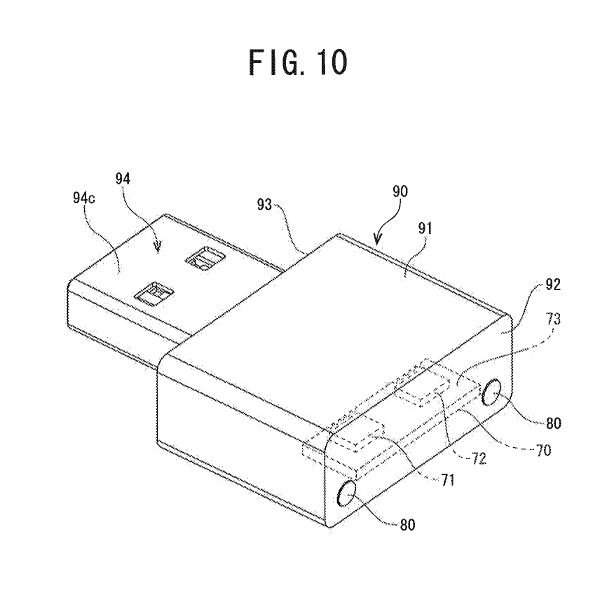

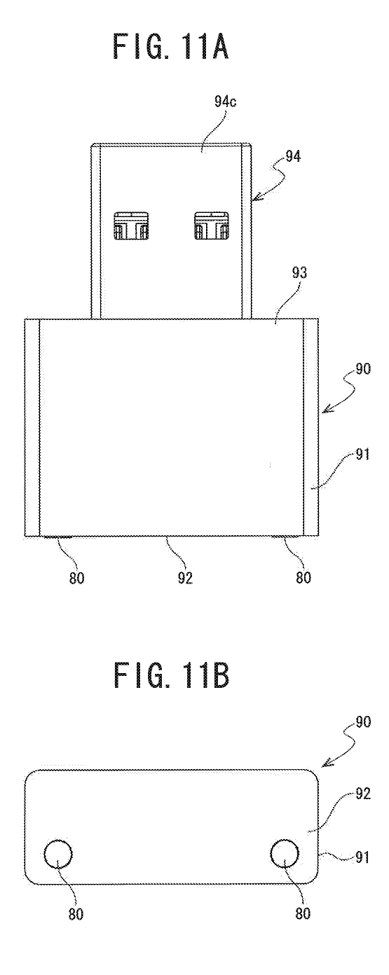

Next, another second connector 90 to be connected with the first connector 10 will be described with reference to FIGS. 10, 11A, 11B, 12A and 12B.

The second connector 90 as shown includes a housing 91 having a substantially rectangular parallelepiped shape, a wireless communication module 70 mounted in the housing 91, and a pair of magnets 80 disposed in the housing 91.

The wireless communication module 70 is same as that shown in FIG. 8, and includes the circuit board 73 the wireless signal transmission IC 71, and the wireless signal reception IC 72. The wireless signal transmission IC 71 and the wireless signal reception IC 72 are mounted on the circuit board 73 having a rectangular shape with the length direction being the width direction (left-right direction of FIG. 10) of the housing 91. The wireless signal transmission IC 71 and the wireless signal reception IC 72 are mounted on the circuit board 73 and to be spaced apart from each other by a predefined interval along a length. The circuit board 73 is disposed in the housing 91 such that the shorter side thereof is orthogonal to a front face 92 of the housing 91, as shown in FIG. 10.

In addition, a pair of magnets 80 are arranged on both sides along a width thereof, in order to interpose the wireless communication module 70 (the circuit board 73) there between, as shown in FIG. 10. Further, each magnet 80 has a cylindrical shape, and is exposed with one end face thereof being almost flush with the front face 92 of the housing 91.

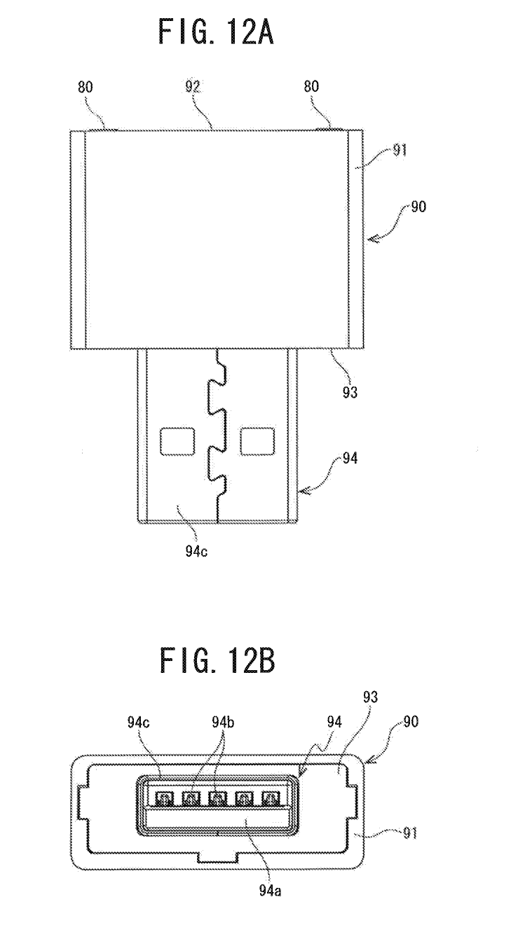

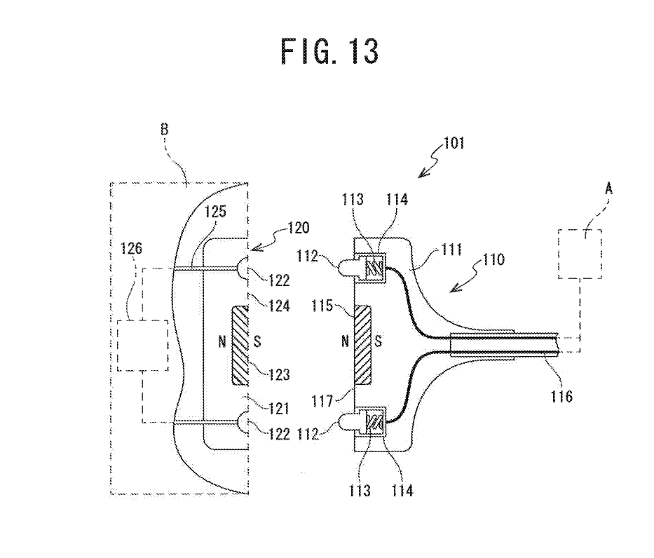

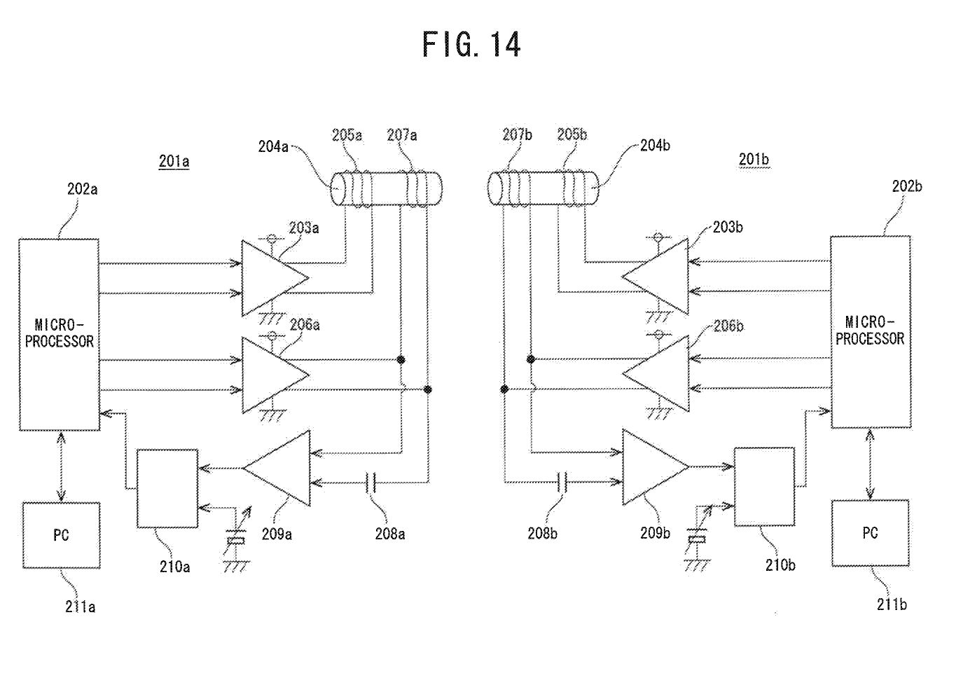

Moreover, a Universal Serial Bus (USB) connector portion 94 is provided on a back face 93 of the housing 91. The USB connector portion 94 includes a housing 94a, multiple contacts 94b disposed in the housing 94a, and a metal shell 94c disposed to surround the circumference of the housing 94a and constituting a mating portion for a mating connector, as shown in FIG. 12A and FIG. 12B. Furthermore, each contact 94b is wired to the circuit board 73.

The second connector 90 with such a configuration is attached to a mobile device using the USB connector portion 94 to, for example, a USB connector portion (not shown) of the mobile device.

Then, in this situation, the planar face 21 of the first connector 10 shown in FIG. 1 and the front face 92 of the second connector 90 face to each other to make each magnet 40 on the planar face 21 of the first connector 10 closer to each magnet 80 on the front face 92 of the second connector 90. This causes each magnet 40 of the first connector 10 and each magnet 80 of the second connector 90 to attract each other, so that the first connector 10 and the second connector 90 are mechanically connected.

It is thus made possible for the wireless communication module 30 of the first connector 10 and the wireless communication module 70 of the second connector 90 to perform data communication at high-speed transmission over the carrier wave of, for example, 30 GHz or higher.

In this manner, since the wireless communication module 30 of the first connector 10 and the wireless communication module 70 of the second connector 90 are capable of performing the data communication, it is possible to provide the connector assembly 1 suited for the high-speed transmission over the carrier wave of, for example, 30 GHz or higher. Moreover, the wireless communication module 70 is mounted in the housing 91. This eliminates the necessity of providing a contact to be arranged to protrude from the front face 92 of the housing 91, thereby resulting in the connector assembly 1 superior in design.

Heretofore, embodiments of the invention have been described, but the present invention is not limited to them. Various modifications and improvements may occur.

For example, the wireless communication modules 30 and 70 are each configured such that the wireless signal transmission IC 31 and the wireless signal reception IC 32 are each constituted of a single ship, and the wireless signal transmission IC 71 and the wireless signal reception IC 72 are each constituted of a single ship. However, the wireless signal transmission IC 31 and the wireless signal reception IC 32 may be collectively constituted of a single ship, and the wireless signal transmission IC 71 and the wireless signal reception IC 72 may be collectively constituted of a single ship.

Additionally, each magnet 40 is exposed with the end face thereof being almost flush with the planar face 21 of the housing 20, and each magnet 80 is exposed with one end face thereof being almost flush with the side face 63 of the housing 61. However, the end face of each magnet 40 and the end face of each magnet 80 may not necessarily be exposed from the planar face 21 and the side face 63, respectively.

Moreover, the number of each of the magnets 40 and 80 may be one, or three or more.

Additionally, the first positioning portion 24 is arranged on the planar face 21 of the first connector 10, and the second positioning portion 62 is arranged on the side face 63 of the second connector 50 so that the first positioning portion 24 can enter the second positioning portion 62. However, the second positioning portion may be arranged on the planar face 21 of the first connector 10, or the first positioning portion to enter the second positioning portion may be arranged on the side face 63 of the second connector 50. Further, no positioning portion may be provided at all on the planar face 21 of the first connector 10 or on the side face 63 of the second connector 50.

Moreover, the power transmission may not necessarily be performed by the magnet 40 of the first connector 10 and the magnet 80 of the second connector 50.

Besides the above description, the configurations described in the above embodiment can be selected or changed as appropriate to other configurations without departing from the spirit and scope of the present invention.

What is claimed is:

1. A connector comprising:
a housing having a planar face;
a wireless communication module disposed in the housing and having a wireless signal transmission integrated circuit (IC) and a wireless signal reception IC; and
a first magnet disposed along the planar face.

2. The connector according to claim 1, further comprising a second magnet disposed opposite the first magnet such that the wireless communication module is interposed there between.

3. The connector according to claim 2, wherein the first magnet is flush with the planar face.

4. The connector according to claim 1, wherein the planar face includes a first positioning portion extending from a surface thereof

5. The connector according to claim 4, wherein the first positioning portion is an elongated member extending along a length of the housing.

6. The connector according to claim 1, wherein the wireless signal transmission IC includes a buffer, a modulation circuit, an amplifier circuit, and a transmission antenna.

7. The connector according to claim 6, wherein the wireless signal reception IC includes a demodulation circuit and a reception antenna.

8. The connector according to claim 1, wherein the wireless signal reception IC includes a demodulation circuit and an antenna.

9. A connector assembly comprising
a first connector having a housing with a planar face with a first positioning portion extending from a surface thereof, a first wireless communication module disposed in the housing, and a first magnet disposed along the planar face;
a second connector having a housing having a second positioning portion shaped to receive the first positioning portion, a second wireless communication module mounted in the housing, and a first magnet disposed in the housing.

10. The connector assembly according to claim 9, wherein the first wireless communication module includes a first wireless signal transmission integrated circuit (IC) and a first wireless signal reception IC.

11. The connector assembly according to claim 10, wherein the housing includes a chassis for a mobile device.

12. The connector assembly according to claim 10, wherein the second wireless communication module includes a second wireless signal transmission IC and a second wireless signal reception IC mounted on a circuit board.

13. The connector assembly according to claim 12, wherein the second wireless signal transmission IC and the second wireless signal reception IC are spaced apart from each other by a predefined interval along a length of the circuit board.

14. The connector assembly according to claim 9, wherein power is transmitted through the first magnet.

15. A wireless communication module comprising:
a wireless signal transmission integrated circuit (IC) having has a buffer, a modulation circuit, an amplifier circuit, and a transmission antenna;
a wireless signal reception IC having a demodulation circuit and a reception antenna; and
a circuit board on which the wireless signal transmission IC and the wireless signal reception IC are mounted.

16. The wireless communication module according to claim 15, wherein the wireless signal transmission IC and the wireless signal reception IC are spaced apart from each other by a predefined interval along a length of the circuit board.
